(19) United States
(12) Patent Application Publication
(10) Pub. No.: US 2026/0114091 A1
(43) Pub. Date: Apr. 23, 2026

(54) DISPLAY PANEL AND DISPLAY DEVICE

(71) Applicant: Tianma Advanced Display Technology Institute (Xiamen) Co., Ltd., Xiamen (CN)

(72) Inventors: Zhenyu Jia, Xiamen (CN); Wenqi Zhou, Xiamen (CN); Wenxin Jiang, Xiamen (CN); Sitao Huo, Xiamen (CN); Tianyi Wu, Xiamen (CN)

(73) Assignee: Tianma Advanced Display Technology Institute (Xiamen) Co., Ltd., Xiamen (CN)

(21) Appl. No.: 19/423,248

(22) Filed: Dec. 17, 2025

(30) Foreign Application Priority Data
Jun. 30, 2025 (CN) 202510892082.3

(51) Int. Cl. H10H 20/853; H10K 59/80; H10K 102/00

(52) U.S. Cl. CPC H10H 20/853; H10K 59/873; H10K 59/8792; H10K 2102/351

(57) ABSTRACT

A display panel includes a base substrate and a display functional layer located on one side of the base substrate. The display panel includes at least one first edge. At the first edge, the base substrate includes a first chamfer and a second chamfer. In a first direction, the first chamfer at least overlaps with a first filling adhesive, and a non-chamfered region or the second chamfer at least overlaps with a second filling adhesive. The viscosity of the second filling adhesive is greater than the viscosity of the first filling adhesive. The first direction is parallel to the plane of the base substrate and intersects the first edge.

### CROSS-REFERENCE TO RELATED APPLICATION

This disclosure claims priority to Chinese Patent Application No. 202510892082.3 filed Jun. 30, 2025, the disclosure of which is incorporated herein by reference in its entirety.

### TECHNICAL FIELD

Embodiments of the present disclosure relate to display technology, and more particularly to a display panel and a display device.

### BACKGROUND

With the development of display technology, narrow-bezel or even bezel-less display panels are becoming increasingly popular. For narrow-bezel or bezel-less display panels, the narrow bezel width results in a narrow region for the film layers of the edge encapsulation structure, which is prone to edge warping or encapsulation failure, thus adversely affecting the display effect. In particular, in the field of outdoor public information displays (PIDs), due to their large display areas, the public information displays are formed typically by splicing multiple bezel-less display panels together, and the structure of the splicing edges of the bezel-less display panels has become a focus of attention.

### SUMMARY

A display panel and a display device are provided according to embodiments of the present disclosure. In the display panel, a first chamfer and a second chamfer are formed on a first edge of the display panel, the first chamfer and the second chamfer are then filled with a first filling adhesive and a second filling adhesive of different viscosities, respectively, the first filling adhesive with a lower viscosity is used first and then the second filling adhesive with a higher viscosity is used, thereby effectively filling the chamfers and improving the encapsulation quality of the display panel edge.

A display panel is provided according to embodiments of the present disclosure, which includes a base substrate and a display functional layer provided on one side of the base substrate. The display panel includes at least one first edge. At the first edge, the base substrate includes a first chamfer located at a side surface of the base substrate facing the display functional layer and a second chamfer located at a side surface of the base substrate away from the display functional layer. In a first direction, the first chamfer at least overlaps with a first filling adhesive, and a non-chamfered region or the second chamfer at least overlaps with a second filling adhesive. The viscosity of the second filling adhesive is greater than the viscosity of the first filling adhesive. The first direction is parallel to a plane in which the base substrate is located, and the first direction intersects the first edge.

A display device is further provided according to embodiments of the present disclosure, which includes a display panel. The display panel includes a base substrate and a display functional layer provided on one side of the base substrate. The display panel includes at least one first edge. At the first edge, the base substrate includes a first chamfer located at a side surface of the base substrate facing the display functional layer and a second chamfer located at a side surface of the base substrate away from the display functional layer. In a first direction, the first chamfer at least overlaps with a first filling adhesive, and a non-chamfered region or the second chamfer at least overlaps with a second filling adhesive. The viscosity of the second filling adhesive is greater than the viscosity of the first filling adhesive. The first direction is parallel to a plane in which the base substrate is located, and the first direction intersects the first edge.

### BRIEF DESCRIPTION OF DRAWINGS

FIG. 1 is a schematic diagram of a partial structure of a display panel provided in an embodiment of the present disclosure;

FIG. 2 is a schematic diagram of another partial structure of a display panel provided in an embodiment of the present disclosure;

FIG. 3 is a schematic diagram of yet another partial structure of a display panel provided in an embodiment of the present disclosure;

FIG. 4 is a schematic diagram of yet another partial structure of a display panel provided in an embodiment of the present disclosure;

FIG. 5 is a schematic diagram of yet another partial structure of a display panel provided in an embodiment of the present disclosure;

FIG. 6 is a schematic diagram of yet another partial structure of a display panel provided in an embodiment of the present disclosure;

FIG. 7 is a schematic diagram of yet another partial structure of a display panel provided in an embodiment of the present disclosure;

FIG. 8 is a schematic diagram of yet another partial structure of a display panel provided in an embodiment of the present disclosure;

FIG. 9 is a schematic diagram of yet another partial structure of a display panel provided in an embodiment of the present disclosure.

FIG. 10 is a schematic diagram of yet another partial structure of a display panel provided in an embodiment of the present disclosure;

FIG. 11 is a schematic diagram of yet another partial structure of a display panel provided in an embodiment of the present disclosure;

FIG. 12 is a schematic top view of multiple display panels spliced together provided in an embodiment of the present disclosure;

FIG. 13 is a schematic sectional view of the multiple display panels spliced together taken along line A1A2 in FIG. 12;

FIG. 14 is another schematic sectional view of the multiple display panels spliced together taken along line A1A2 in FIG. 12;

FIG. 15 is a schematic sectional view of the multiple display panels spliced together taken along line B1B2 in FIG. 12;

FIG. 16 is another schematic sectional view of the multiple display panels spliced together taken along line B1B2 in FIG. 12; and

FIG. 17 is a schematic structural diagram of a display device provided in an embodiment of the present disclosure.

### DETAILED DESCRIPTION

The present disclosure is further described in detail below in conjunction with the drawings and embodiments. It may be understood that the embodiments described herein are only intended to explain the present disclosure, not to limit the present disclosure. It should also be noted that, for the convenience of description, only part of the structure related to the present disclosure, rather than all of it, is shown in the drawings.

The terms used in the embodiments of the present disclosure are to describe specific embodiments only and are not intended to limit the present disclosure. It should be noted that directional terms such as “upper,” “lower,” “left,” and “right” described in the embodiments of the present disclosure are described from the perspectives shown in the drawings and should not be construed as limitations to the embodiments of the present disclosure. Furthermore, it should be understood that, in this context, when an element is referred to as being formed “on” or “under” another element, it can be formed not only directly “on” or “under” the other element, but also indirectly “on” or “under” the other element through an intermediate element. Terms such as “first” and “second” are used for descriptive purposes only and do not indicate any order, quantity, or importance; they are simply used to distinguish different components. The person skilled in the art will understand the specific meanings of the above terms in the present disclosure based on specific circumstances.

To address the edge encapsulation issues of narrow-bezel or bezel-less display panels, embodiments of the present disclosure provide a display panel including a base substrate and a display functional layer provided on one side of the base substrate. The display panel includes at least one first edge, and at the first edge, the base substrate includes a first chamfer located at a side surface of the base substrate facing the display functional layer and a second chamfer located at a side surface of the base substrate away from the display functional layer. In a first direction, the first chamfer at least overlaps with a first filling adhesive, and a non-chamfered region or the second chamfer at least overlaps with a second filling adhesive. The viscosity of the second filling adhesive is greater than that of the first filling adhesive. The first direction is parallel to a plane in which the base substrate is located, and the first direction intersects the first edge.

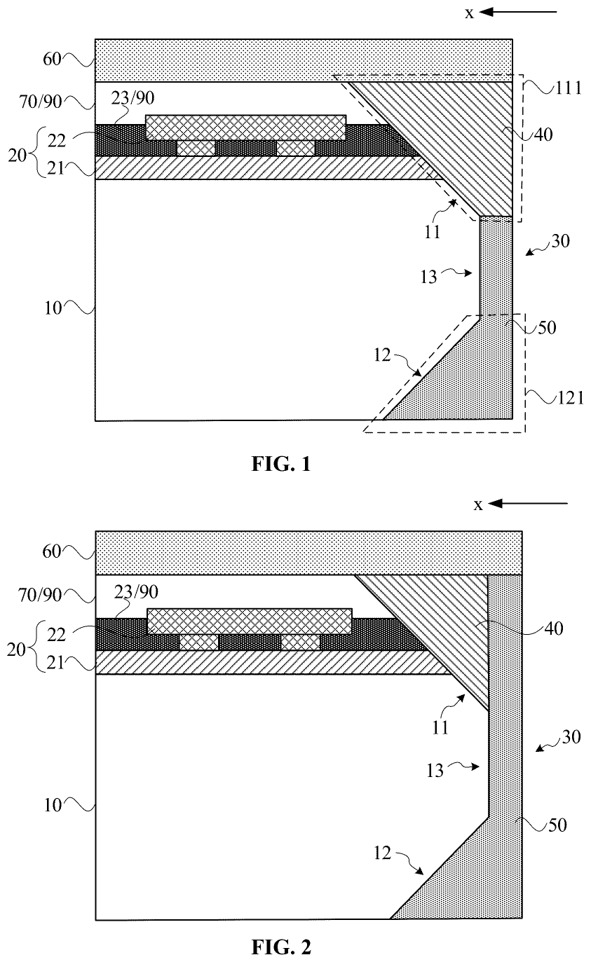

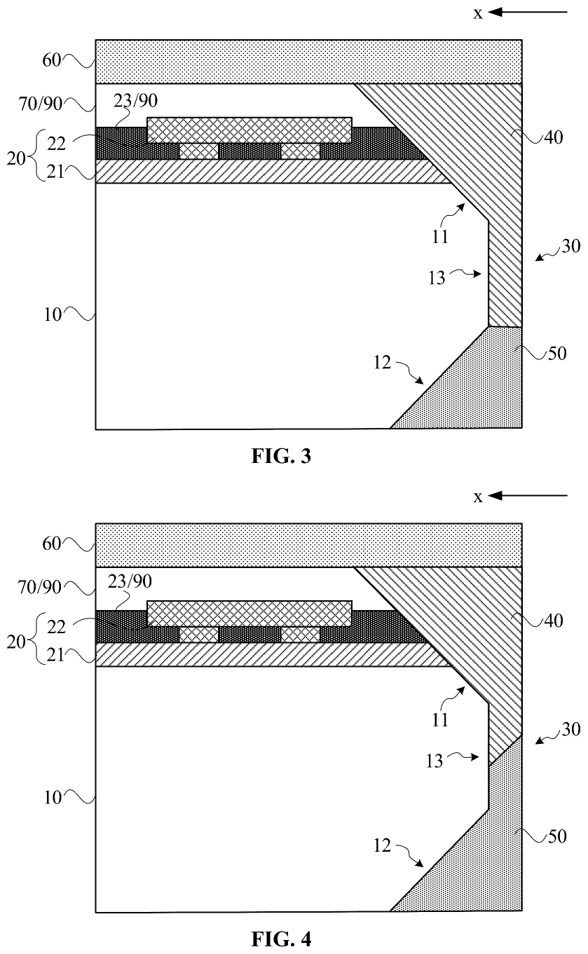

Schematically, FIG. 1 is a schematic diagram of a partial structure of a display panel provided in an embodiment of the present disclosure; FIG. 2 is a schematic diagram of another partial structure of a display panel provided in an embodiment of the present disclosure; and FIG. 3 is a schematic diagram of yet another partial structure of a display panel provided in an embodiment of the present disclosure. FIG. 1 to FIG. 3 illustrate the structure of part of a display region and the first edge of a display panel. The display panel includes a base substrate 10 and a display functional layer 20 provided on one side of the base substrate 10. The base substrate 10 may be a glass substrate that provides support. The display functional layer 20 is provided on the base substrate 10 and may include a pixel circuit layer 21 (the specific structure of the pixel circuit layer 21 is not shown in FIG. 1 to FIG. 3) and light-emitting elements 22. The display panel may further include a light-shielding layer 23/90. The pixel circuit layer 21 is provided with a pixel circuit array, and a pixel circuit in the pixel circuit array drives a light-emitting element 22 to emit light. The pixel circuits in the pixel circuit layer 21 are configured to drive the light-emitting elements 22 to emit light. Therefore, in this embodiment of the present disclosure, the pixel circuit layer 21 and the light-emitting elements 22 are collectively referred to as the display functional layer. In other embodiments, it may take only the light-emitting elements 22 and related film layers (such as a light-shielding layer and an insulating layer around the light-emitting element electrodes) as the display functional layer. The light-emitting element 22 may be an organic light-emitting diode (OLED), a sub-millimeter light-emitting diode (Mini LED), or a micro light-emitting diode (Micro LED), which may be designed according to practical conditions in specific implementations and is not limited to this embodiment of the present disclosure. FIG. 1 to FIG. 3 only schematically illustrate a light-emitting element 22 located at the edge of the display region. In the display region of the display panel, multiple light-emitting elements arranged in an array are provided, where the light-emitting elements may include red light-emitting elements, green light-emitting elements, and blue light-emitting elements to achieve color display. The display panel includes at least one first edge 30. At the first edge, the base substrate 10 includes a first chamfer 11 located at a side surface of the base substrate 10 facing the display functional layer 20 and a second chamfer 12 located at a side surface of the base substrate 10 away from the display functional layer 20. Referring to FIG. 1, in a first direction x, the first chamfer 11 overlaps with a first filling adhesive 40, while a non-chamfered region 13 (located in a region between the first chamfer 11 and the second chamfer 12 of the sidewall of the base substrate 10) and the second chamfer 12 both overlap with the second filling adhesive 50. Referring to FIG. 2, in the first direction x, the first chamfer 11 overlaps with the first filling adhesive 40, while the first chamfer 11, the non-chamfered region 13, and the second chamfer 12 all overlap with the second filling adhesive 50. Referring to FIG. 3, in the first direction x, the first chamfer 11 and the non-chamfered region 13 all overlap with the first filling adhesive 40, while the second chamfer 12 overlaps with the second filling adhesive 50. The first direction x is parallel to the plane in which the base substrate 10 is located, and the first direction x intersects the first edge 30, meaning that the first direction x is the direction from the first edge 30 of the display panel toward the display region. The provision of the first chamfer 11 and the second chamfer 12 increases the contact area between the filling adhesive and the edge of the display panel, improving the encapsulation yield. Furthermore, the viscosity of the second filling adhesive 50 is set to be greater than that of the first filling adhesive 40, and the elasticity of the second filling adhesive 50 is set to be greater than that of the first filling adhesive 40. In encapsulating the side edges of the display panel, the first filling adhesive 40 with a lower viscosity is first applied, and due to its lower viscosity, the first filling adhesive 40 has better fluidity, which reduces bubbles and other defects formed in filling the edge region of the display functional layer. The second filling adhesive 50 with a higher viscosity is then applied for the second time to fill the edge of the base substrate 10, achieving a better encapsulation effect.

Continuing to refer to FIG. 1 and FIG. 2, at the first edge, an edge (i.e., the end surface connecting top and bottom surfaces of the display functional layer; the display functional layer, the end surface of the display functional layer, and the specific composition of the end surface will be described in detail below; hereinafter, it will be directly referred to as the edge of the display functional layer 20) region of a side edge, on a side facing away from the display region, of the display functional layer 20 exhibits a machined planar shape. That is, the plane formed by the edge of the display functional layer 20 is coplanar with a surface of the first chamfer. As a result, the projection of the first filling adhesive 40 in a region where the first chamfer is located on a first plane, as a whole, is triangular (or trapezoidal). The first plane is perpendicular to the plane in which the display panel is located, and the first plane is also perpendicular to the first edge.

It should be understood that FIG. 1 to FIG. 3 illustrate sectional views of partial structures of the display panel taken along the first plane. In this embodiment, machining the edge of the display functional layer 20 into a flat surface can prevent steps from being formed between different film layers and prevent insufficient adhesive filling due to a gap. Setting the first filling adhesive 40 into the triangular shape facilitates an increase in the thickness of the first filling adhesive 40 and its contact area with the edge, thereby improving the encapsulation effect.

In the technical solution of the embodiments of the present disclosure, the region where the first chamfer is located is closer to the display functional layer than the region where the second chamfer is located. Since the display functional layer includes multiple stacked film layers, the multiple film layer structures may have a gap therebetween and have a complex border. The display effect may be adversely affected if the encapsulation is poor. Therefore, in encapsulating, the region where the first chamfer is located is first filled with a first filling adhesive with a lower viscosity, the first filling adhesive has a lower viscosity, and therefore has a better fluidity, thereby preventing the formation of air bubbles in the filling adhesive. The region where the second chamfer is located is on the back of the display panel, and the region where the second chamfer is located is filled with a second filling adhesive with a higher viscosity. The second filling adhesive may further cover the non-chamfered region, thereby effectively filling the chamfers and improving the encapsulation effect of the display panel edge.

The inventors have discovered that to achieve a bezel-less display, side edge wires are often arranged to extend along the side edge of the display panel to the back of the display panel. Encapsulating the side edge wires requires encapsulating the sidewalls of the display panel; therefore, due to the insufficient filling space for the encapsulation adhesives, edge encapsulation is prone to failure.

In embodiments of the present disclosure, by providing chamfers and then filling the chamfers with the first and second filling adhesives, edge encapsulation failure is avoided. Furthermore, the bezel-less display panel may also be used for a spliced display. Embodiments of the spliced display are described in detail below.

Continuing to refer to FIG. 1, in one or more embodiments, the first chamfer is filled with the first filling adhesive 40, and the second chamfer is filled with the second filling adhesive 50.

It may be appreciated that the first chamfer 11 and second chamfer 12 of the base substrate 10 create spaces for the corresponding filling adhesives. The region defined by the dashed box 111 in FIG. 1 represents the space formed by the first chamfer, i.e., the first chamfer is filled with the first filling adhesive 40. The region defined by the dashed box 121 represents the space formed by the second chamfer, i.e., the second chamfer is filled with the second filling adhesive 50.

Continuing to refer to FIG. 1 to FIG. 3, in one or more embodiments, the display panel further includes a surface film 60 located on the side of the display functional layer 20 facing away from the base substrate. The surface film 60 may be attached to the surface of the display functional layer 20 via an optical clear adhesive (OC) layer 70/90, with at least part of an end surface of the second filling adhesive 50 facing away from the display region flush with the end surface of the surface film 60 at the first edge 30.

The surface film 60 may be a 3A film material that provides anti-glare (AG), anti-fingerprint (AF), and anti-reflection (AR) functions, or a 2A film material that provides two of the three functions, or a composite film material with more functions. The surface film 60 may protect the display functional layer 20 and may also provide AG, AF, AR, and other functions. The functions of the surface film 60 may be designed based on practical conditions in specific implementations, and this is not limited to this embodiment of the present disclosure. It may be understood that the first filling adhesive 40 and the second filling adhesive 50 may be arranged differently due to differences in the amount of adhesive used in encapsulating and the encapsulation method. In one or more embodiments, in the region where the first chamfer 11 is located or in the first chamfer 11 and the non-chamfered region 13, the second filling adhesive 50 exposes an end surface of the first filling adhesive 40 facing away from the display region, and the end surface of the first filling adhesive 40 facing away from the display region, an end surface of the second filling adhesive 50 facing away from the display region, and an end surface of the surface film 60 at the first edge 30 are flush with each other. The non-chamfered region 13 in this embodiment of the present disclosure refers to the region of the base substrate 10 between the first chamfer 11 and the second chamfer 12.

In one or more embodiments, the first filling adhesive 40 covers the region where the first chamfer is located, and the second filling adhesive 50 covers the region where the second chamfer is located; one or both of the first filling adhesive 40 and the second filling adhesive 50 cover the non-chamfered region. The first filling adhesive 40 and the second filling adhesive 50 are contiguous with each other and edges of the first filling adhesive 40 and the second filling adhesive 50 facing toward an outer side of the base substrate 10 are flush.

For example, in the embodiment shown in FIG. 1, an interface between the first filling adhesive 40 and the second filling adhesive 50 is located below the first chamfer, meaning that end surfaces of the surface film 60, the first filling adhesive 40, and the second filling adhesive 50 at the first edge 30 are flush with each other. In other words, in the embodiment shown in FIG. 1, the edge of the first filling adhesive 40 is flush with the first edge 30 of the display panel. The first filling adhesive 40 and the second filling adhesive 50 are arranged in the direction from the surface film 60 toward the base substrate 10. In the first direction x, the second filling adhesive 50 covers the non-chamfered region 13 at the side edge of the base substrate. In the embodiment shown in FIG. 2, in one or more embodiments, in the first direction x, the first chamfer 11 overlaps with the second filling adhesive 50, and the end surface of the second filling adhesive 50 on the side facing away from the display region is flush with the end surface of the surface film 60 at the first edge 30. In other words, the interface between the first filling adhesive 40 and the second filling adhesive 50 is located to the right of the region where the first chamfer 11 is located (corresponding to the direction in FIG. 2; and in various embodiments of the present disclosure, the up, down, left, and right directions described correspond to the directions in the drawings). That is, the second filling adhesive 50 covers the first filling adhesive 40, i.e., the end surfaces of the surface film 60 and the second filling adhesive 50 at the first edge 30 are flush; and the second filling adhesive 50 contacts the surface of the surface film 60 facing the side of the base substrate 10, thereby completely encapsulating the first filling adhesive 40 within the region where the first chamfer 11 is located, which is conductive to improving the encapsulation effect. In the embodiment shown in FIG. 3, the interface between the first filling adhesive 40 and the second filling adhesive 50 is located below the non-chamfered region 13. That is, the end surfaces of the surface film 60, the first filling adhesive 40, and the second filling adhesive 50 at the first edge 30 are flush. The edge of the first filling adhesive 40 is flush with the first edge 30 of the display panel. The first filling adhesive 40 and the second filling adhesive 50 are arranged in the direction from the surface film 60 toward the base substrate 10. In the first direction x, the first filling adhesive 40 covers the non-chamfered region 13 at the side edge of the base substrate 10. In other embodiments, it is also possible to design the first filling adhesive 40 to cover the upper half of the non-chamfered region, and design the second filling adhesive 50 to cover the lower half of the non-chamfered region, which can be designed based on practical conditions in specific implementations and is not limited to the embodiments of the present disclosure.

FIG. 4 is a schematic diagram of yet another partial structure of a display panel provided in an embodiment of the present disclosure. Referring to FIG. 4, in one or more embodiments, in the non-chamfered region 13 between the first chamfer 11 and the second chamfer 12, the first filling adhesive 40 and the second filling adhesive 50 overlap in the first direction x. In the overlapping region, the first filling adhesive 40 is located on the side of the second filling adhesive 50 facing the base substrate 10.

It may be understood that due to the fluidity of the filling adhesive, when the first filling adhesive 40 is filled into the first chamfer 11, part of the first filling adhesive 40 may remain in the non-chamfered region 13 due to overflow of the first filling adhesive 40. This means that the first filling adhesive 40 forms a slope in the non-chamfered region 13. When the second filling adhesive 50 is then filled, the second filling adhesive 50 forms a slope complementary to the first filling adhesive 40, such that the structure shown in FIG. 4 is formed.

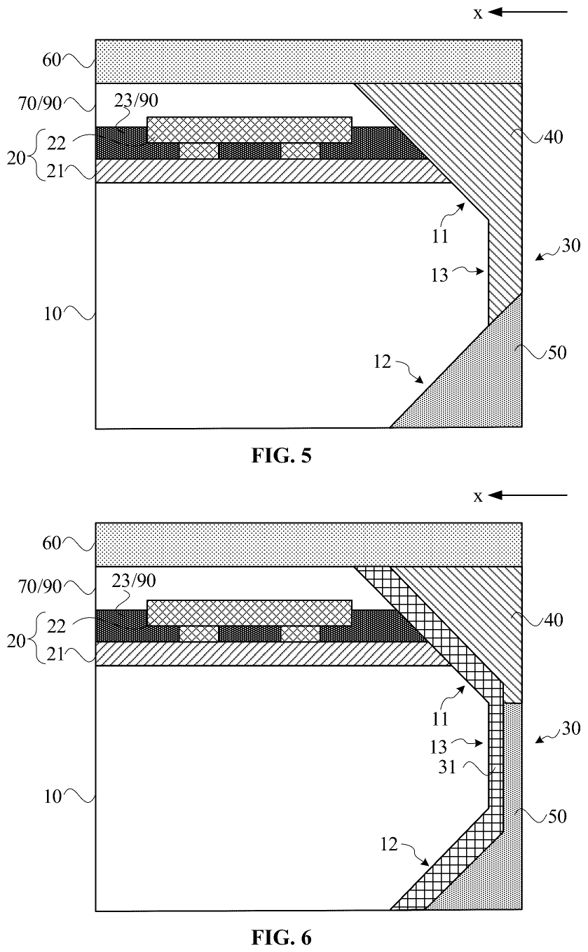

FIG. 5 is a schematic diagram of yet another partial structure of a display panel provided in an embodiment of the present disclosure. Referring to FIG. 5, in one or more embodiments, the first filling adhesive 40 extends to the second chamfer 12, and the surface of the first filling adhesive 40 facing the second chamfer 12 is contiguous and coplanar with a surface of the second chamfer 12.

It will be appreciated that, similar to the embodiment shown in FIG. 4, the first filling adhesive 40 extends to the non-chamfered region 13, but does not cover the second chamfer. Therefore, in this embodiment, the first filling adhesive 40 is configured to extend to the edge of the second chamfer 12. The surface of the first filling adhesive 40 facing the side of the second chamfer 12 is coplanar with the surface of the second chamfer 12, marking the limit position of the extension of the first filling adhesive 40.

FIG. 6 is a schematic diagram of yet another partial structure of a display panel provided in an embodiment of the present disclosure. Referring to FIG. 6, in one or more embodiments, the first edge 30 is further provided with a side edge encapsulation layer 31. The side edge encapsulation layer 31 covers the side edge of the display functional layer 20 and the side edge of the base substrate 10 at the first edge 30, in a direction perpendicular to the first edge 30 and parallel to the plane in which the display panel is located, i.e., in the first direction x. It should be noted that the first edge described here refers to a line as which the edge of the display panel is viewed from the macroscopic view, or an extension direction of the outer contour of the display panel when the display panel is viewed from the top.

The side edge encapsulation layer 31 may effectively encapsulate the edge of the display functional layer 20, reducing the risk of failure of the display functional layer 20 due to water and oxygen intrusion. Furthermore, the side edge encapsulation layer 31 may be set as a highly viscous material to enhance the securement between the first edge 30 and the first filling adhesive 40, as well as between the first edge 30 and the second filling adhesive 50.

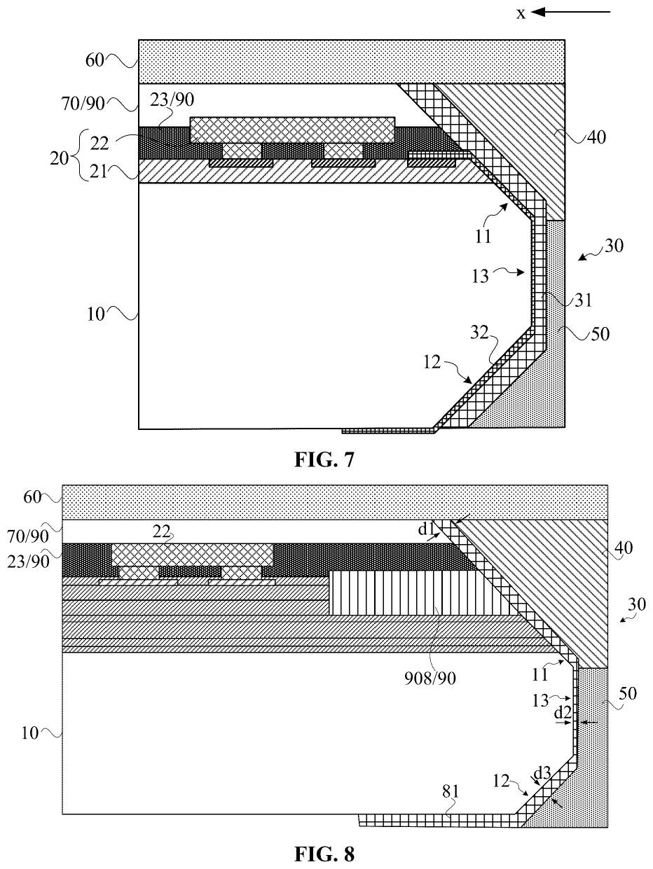

FIG. 7 is a schematic diagram of yet another partial structure of a display panel provided in an embodiment of the present disclosure. Referring to FIG. 7, in one or more embodiments, the first edge 30 is further provided with a side edge wire 32. A first end of the side edge wire 32 is located within the display functional layer 20, and the side edge wire 32 extends along the edge of the base substrate 10 to the surface of the base substrate 10 away from a side of the display functional layer 20.

For a bezel-less display panel, to achieve a bezel-less display effect, structures such as the driver chip can be set on the back of the display panel. The side edge wires are then utilized to connect the driver chip to the circuitry within the display region. This arrangement can reduce the display panel's bezel and enables the light-emitting elements at the edge of the display region to be set as close to the edge as possible, thereby achieving a visually bezel-less effect.

Continuing to refer to FIG. 7, in one or more embodiments, the display panel further includes a side edge encapsulation layer 31. The side edge encapsulation layer 31 covers the side edge wire 32 located at the edge of the base substrate 10 and covers at least part of the side edge wire 32 located at the surface, away from the side of the display functional layer 20, of the base substrate 10.

The side edge encapsulation layer 31 protects the side edge wire 32, preventing defects such as breakage of the side edge wire 32. In specific implementations, the side edge encapsulation layer 31 can be a clear or black encapsulation adhesive layer, and the design of which can be tailored to the practical conditions in specific implementations.

In a certain embodiment, in one or more embodiments, the display panel further includes a protective layer. The projection of the protective layer on the first edge of the display panel covers the surface of the first chamfer 11, the surface of the second chamfer 12, and the non-chamfered region between the first chamfer and the second chamfer.

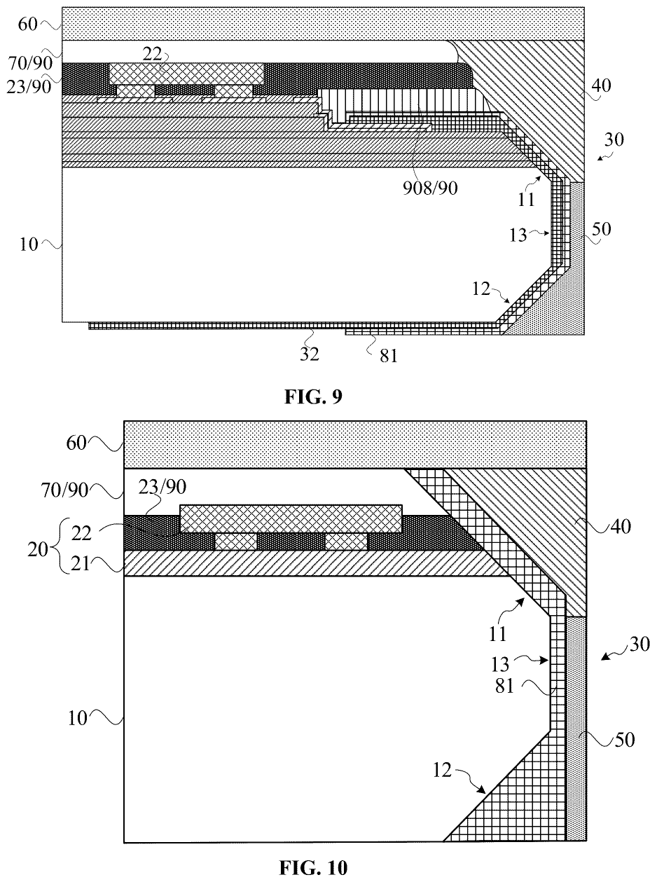

For example, FIG. 8 is a schematic diagram of yet another partial structure of a display panel provided in an embodiment of the present disclosure, and FIG. 9 is a schematic diagram of yet another partial structure of a display panel provided in an embodiment of the present disclosure. Referring to FIG. 8 and FIG. 9, in one or more embodiments, the protective layer includes a first protective layer 81. In the region where the first chamfer 11 is located, the first protective layer 81 is located on the side of the first filling adhesive 40 facing the base substrate 10. In the non-chamfered region 13, the first protective layer 81 is located on the side of the first filling adhesive 40 or the second filling adhesive 50 facing the base substrate 10. In the region where the second chamfer 12 is located, the first protective layer 81 is located on the side of the second filling adhesive 50 facing the base substrate 10.

The first protective layer 81 can be used to increase the bonding strength between the display panel and the first filling adhesive 40 or the second filling adhesive 50. For the embodiment shown in FIG. 9 that includes the side edge wire 32, the first protective layer 81 can be used to protect the side edge wire 32. Its structure and effect are similar to those of the side edge encapsulation layer in the embodiment described above.

In one or more embodiments, the display panel further includes at least one first functional layer 90 located on the side of the base substrate 10 facing the display functional layer 20 and facing the first edge 30 (the first functional layer includes at least a filling layer 908, a light-shielding layer 23, and an optical clear adhesive layer 70, which are stacked sequentially in the direction from the base substrate 10 toward the display functional layer 20). The first protective layer 81 further covers an end surface of the first functional layer 90 on the side facing away from the display region (FIG. 8), or one end of the first protective layer 81 extends into the interior of the display functional layer 20 (FIG. 9).

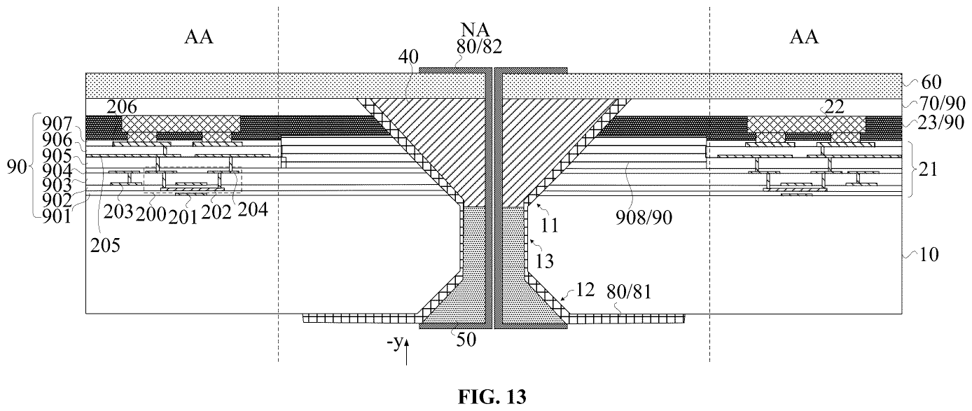

It may be understood that since the display functional layer in the display region includes structures such as a semiconductor active layer, multiple metal layers, multiple insulating layers, and a planarization layer, some film layers terminate within the display region rather than at the edge of the display functional layer, this is particularly true for bezel-less splicing display panels, which, due to their bezel-less nature, generally require a minimal encapsulation layer thickness to minimize the visibility of the splicing seam after the bezel-less splicing display panels are spliced. To prevent delamination of organic layers, such as the planarization layer, trenching at the position near the edge is necessary. This results in the edge of the display functional layer having different heights due to the difference in the film layers, forming a gap. In order to compensate for the gap, a first functional layer 90 can be formed on the base substrate 10. FIG. 8 and FIG. 9 only schematically show one first functional layer 908/90. In specific implementations, the lower insulating layer (not shown in FIG. 8 and FIG. 9, reference may be made to the embodiments shown in FIG. 13 to FIG. 16 for details), the upper light-shielding layer 23/90, an optical clear adhesive layer 70/90, and other film layers can all be regarded as the first functional layers.

Continuing to refer to FIG. 8, in one or more embodiments, a first protective layer thickness d1 in the region where the first chamfer 11 is located is greater than a first protective layer thickness d2 in the non-chamfered region, and a first protective layer thickness d3 in the region where the second chamfer 12 is located is greater than the first protective layer thickness d2 in the non-chamfered region.

Since the surface of the first chamfer 11 and the surface of the second chamfer 12 are inclined, the region where the first chamfer 11 is located and the region where the second chamfer 12 is located each have a larger space relative to the non-chamfered region. Therefore, the first protective layer thickness of the region where the first chamfer 11 is located and the first protective layer thickness of the region where the second chamfer 12 is located can be set greater to improve the protective effect.

In another embodiment, the second chamfer can be directly filled with the protective layer. Schematically, FIG. 10 is a schematic diagram of yet another partial structure of a display panel provided in an embodiment of the present disclosure. Referring to FIG. 10, the second chamfer can be directly filled with the first protective layer 81, and then the second filling adhesive 50 is applied on the outside of the first protective layer 81 to achieve a good encapsulation effect.

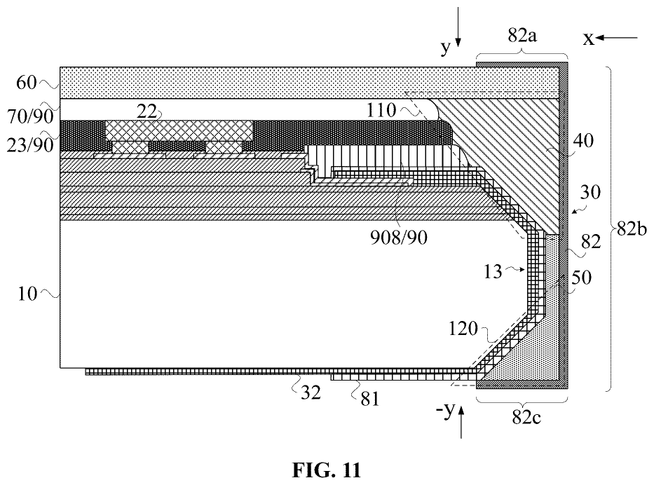

FIG. 11 is a schematic diagram of yet another partial structure of a display panel provided in an embodiment of the present disclosure. Referring to FIG. 11, in one or more embodiments, the protective layer includes a second protective layer 82. In the region where the first chamfer 11 is located, the second protective layer 82 is located on the side of the first filling adhesive 40 facing away from the base substrate 10. In the non-chamfered region 13, the second protective layer 82 is located on the side of the first filling adhesive 40 or the second filling adhesive 50 facing away from the base substrate 10. In the region where the second chamfer 12 is located, the second protective layer 82 is located on the side of the second filling adhesive 50 facing away from the base substrate 10.

It may be understood that the protective layer shown in FIG. 11, including the first protective layer 81 and the second protective layer 82, is merely illustrative. In other implementations, the protective layer may include only the first protective layer 81 or only the second protective layer 82, and the design of which can be tailored to the practical conditions in specific implementations. In one or more embodiments, the protective layer is a blackened layer.

It may be understood that the first protective layer 81 and/or the second protective layer 82 can be configured as blackened layers. In specific implementations, it is possible to configure only the first protective layer 81 as a blackened layer to prevent side edge wires from adversely affecting the display effect due to factors such as reflecting light; it is also possible to configure only the second protective layer 82 as a blackened layer to shield the first filling adhesive 40 and the second filling adhesive 50; or it is possible to configure both the first protective layer 81 and the second protective layer 82 as blackened layers; and it is also possible to configure the first protective layer 81 as a clear encapsulation layer and the second protective layer 82 as a blackened layer, which can be designed based on practical conditions in specific implementations and is not limited to the embodiments of the present disclosure.

Continuing to refer to FIG. 11, in one or more embodiments, the second protective layer 82 includes a first region 82a, a second region 82b, and a third region 82c connected in sequence. In a direction y from the display functional layer 20 toward the base substrate 10, the first region 82a covers the first chamfer 11. In the first direction x, the second region 82b covers the first edge 30. In a direction −y from the base substrate 10 toward the display functional layer 20, the third region 82c covers the second chamfer 12.

The first chamfer 11 and the second chamfer 12 are non-display structures. In specific implementations, the second protective layer 82 can be configured as a blackened layer to prevent the edges from adversely affecting the display effect. It should be noted that the practical proportions of the first chamfer 11 and the second chamfer 12 are very small. The figures in this application are only for illustrating the structures of the chamfers and do not represent the practical dimensions or proportions of the chamfers.

In one or more embodiments, a region 110 enclosed by the first region 82a, a first part of the second region of the second protective layer, and the first chamfer 11 is filled with the first filling adhesive 40. A region 120 enclosed by the third region 82c, a second part of the second region of the second protective layer, and the second chamfer 12 is filled with the second filling adhesive 50. The space between a third part of the second region of the second protective layer and the non-chamfered region 13 may be filled with at least one of the first filling adhesive 40 and the second filling adhesive 50 (FIG. 11 schematically shows that the second filling adhesive 50 is used to fill; in other embodiments, the first filling adhesive 40 may be used to fill, or both the first filling adhesive 40 and the second filling adhesive 50 may be used to fill). The first part of the second region, the third part of the second region, and the second part of the second region are sequentially arranged in the direction y from the display functional layer 20 toward the base substrate 10, such that the second protective layer 82 surrounds the chamfered regions and the first edge 30.

The display panel provided in this embodiment of the present disclosure can be used in the PID field by splicing multiple such display panels. In one or more embodiments, the first edge is a splicing edge, and at least two such display panels are spliced together, with the splicing edge of one display panel adjacent to the splicing edge of another display panel.

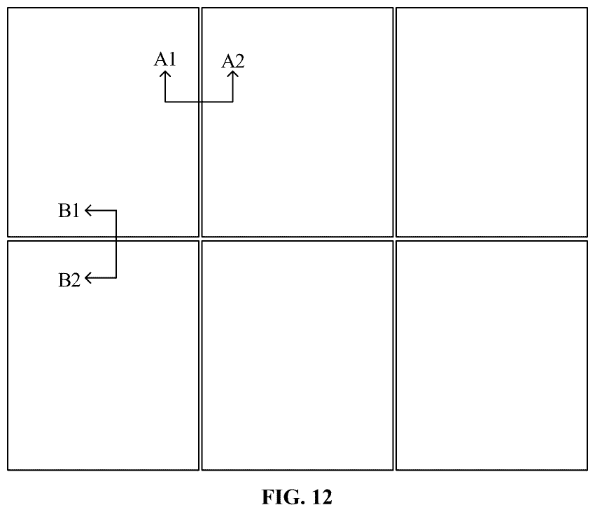

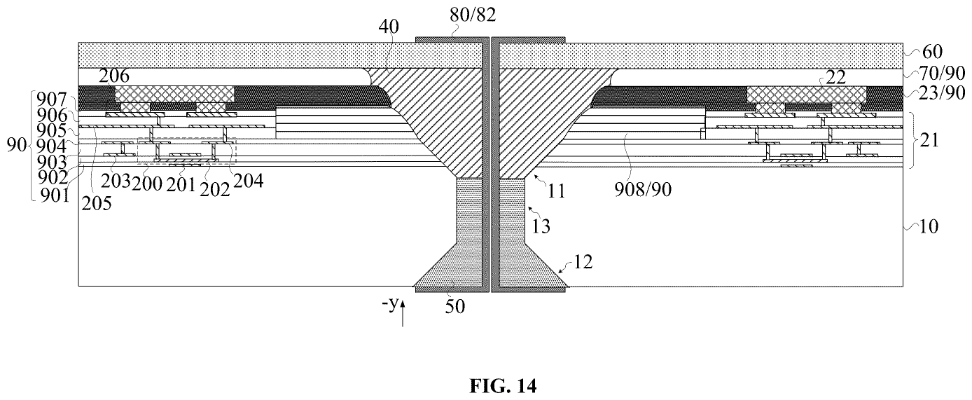

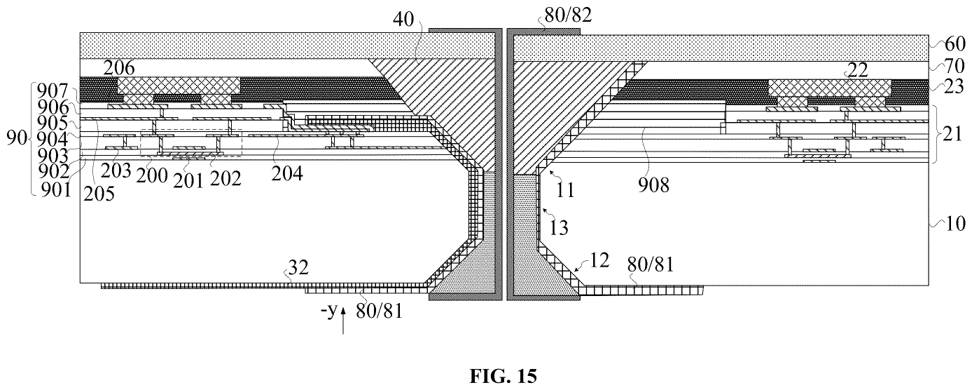

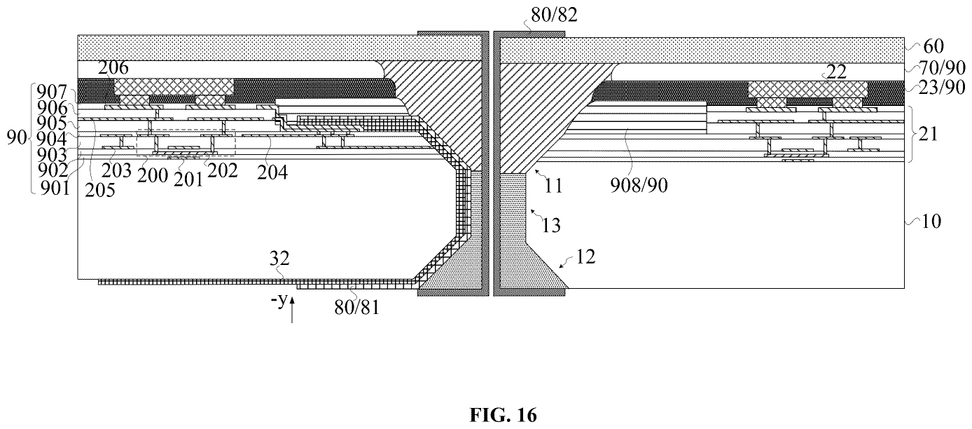

For example, FIG. 12 is a schematic top view of multiple display panels spliced together in an embodiment of the present disclosure, FIG. 13 is a schematic sectional view of the multiple display panels spliced together taken along line A1A2 in FIG. 12, FIG. 14 is another schematic sectional view of the multiple display panels spliced together taken along line A1A2 in FIG. 12, FIG. 15 is a schematic sectional view of the multiple display panels spliced together taken along line B1B2 in FIG. 12, and FIG. 16 is another schematic sectional view of the multiple display panels spliced together taken along line B1B2 in FIG. 12. It may be understood that the left figures in FIG. 13 and FIG. 14 show sectional views of the right bezel positions of the display panels, and the right figures show sectional views of the left bezel positions of adjacent display panels, and side edge wires are usually not designed on the left and right bezels, so there is no side edge wires in FIG. 13 and FIG. 14. The left figures in FIG. 15 and FIG. 16 show sectional views of the lower bezel positions of the display panels, and the right figures show sectional views of the upper bezel positions of adjacent display panels, so the side edge wires 32 are provided in the left figures. In another embodiment, side edge wires can be provided on both the upper and lower bezels of the display panels. In this case, both the left and right figures in FIG. 15 or FIG. 16 include side edge wires.

In one or more embodiments, referring to FIG. 13 or FIG. 15, the display panel further includes multiple first functional layers 90 located between the surface film 60 and the base substrate 10. The end surfaces of the first functional layers 90 facing the side of the first edge are contiguous and coplanar with the surface of the first chamfer 11. Alternatively, referring to FIG. 14 or FIG. 16, at least part of the first functional layers 90 extends toward the surface film 60 in the extension direction of the surface of the first chamfer 11.

In one or more embodiments, the display panel further includes at least one first functional layer 90 located between the surface film 60 and the base substrate 10. The first functional layer 90 includes multiple sub-layers stacked sequentially in the direction from the base substrate 10 toward the display functional layer 20, i.e., the −y direction. Based on this direction, the end surfaces of the sub-layers are sequentially tapered toward the display region in the direction from the first edge toward the display region, forming a profile of the first functional layer in a shape of step or slope. In one or more embodiments, the sub-layers include one or more of multiple insulating layers, a light-shielding layer, and an optical clear adhesive layer.

For example, referring to FIG. 13 to FIG. 16, the display region of the display panel includes a first metal layer 201, a first insulating layer 901, a semiconductor active layer 202, a second insulating layer 902, a second metal layer 203, a third insulating layer 903, a third metal layer 204, a fourth insulating layer 904, a first planarization layer 905, a fourth metal layer 205, a second planarization layer 906, a fifth metal layer 206, a fifth insulating layer 907, a light emitting element 22, a black matrix (light-shielding layer) 23/90, an optical clear adhesive layer 70/90 and a surface film 60 sequentially stacked on one side of the base substrate 10. The first metal layer 201, the first insulating layer 901, the semiconductor active layer 202, the second insulating layer 902, the second metal layer 203, the third insulating layer 903, the third metal layer 204, the fourth insulating layer 904, the first planarization layer 905, the fourth metal layer 205, the second planarization layer 906 and the fifth metal layer 206 can be considered to belong to the pixel circuit layer 21. In the embodiments shown in FIG. 13 and FIG. 15, the edges of the first insulating layer 901, the second insulating layer 902, the third insulating layer 903, the fourth insulating layer 904, the first planarization layer 905, the second planarization layer 906, the fifth insulating layer 907, the filling layer 908, the black matrix (light-shielding layer) 23/90 and the optical clear adhesive layer 70/90 facing the side of the first chamfer 11 are all flat surfaces and coplanar with the surface of the first chamfer 11. This arrangement is conducive to the flow of the first filling glue 40 and avoids the generation of bubbles and other defects in the first filling adhesive 40 during filling. In the embodiments shown in FIG. 14 and FIG. 16, the edges of the first insulating layer 901, the second insulating layer 902, the third insulating layer 903, the fourth insulating layer 904, the first planarization layer 905, the second planarization layer 906, the fifth insulating layer 907 facing the side of the first chamfer 11 are all flat surfaces and are coplanar with the surface of the first chamfer 11, and the edges of the filling layer 908, the black matrix (light-shielding layer) 23/90 and the optical clear adhesive layer 70/90 facing the side of the first chamfer 11 are all curved surfaces. Since the filling layer 908, the black matrix (light-shielding layer) 23/90, and the optical clear adhesive layer 70/90 are typically made of organic materials, they may form curved surfaces at the edges due to overflow and other factors during preparation. This can relieve internal stress in the film layers, and the curved surfaces can increase the surface areas of the edges, thereby improving the performance of bonding with the first filling adhesive 40 and compensating for the insufficient viscosity of the first filling adhesive 40. The first metal layer 201 is located below the semiconductor active layer 202 and provides light shielding to prevent external light from adversely affecting the performance of the semiconductor active layer 202. The semiconductor active layer 202 can be a polysilicon active layer or an oxide semiconductor active layer according to practical requirements, and in some embodiments, both semiconductor active layers can be provided. The second metal layer 203 can form the gate of the transistor, and the third metal layer 204 can form the source and drain of the transistor. FIG. 13 to FIG. 16 schematically illustrate only one transistor 200. Furthermore, the second metal layer 203, the third metal layer 204, the fourth metal layer 205, and the fifth metal layer 206 can be designed to provide internal wires for the display panel based on practical requirements. The specific design can be selected based on practical requirements. For example, in an embodiment including the side edge wire, the side edge wire is connected to the second metal layer 203, the third metal layer 204, the fourth metal layer 205, and the fifth metal layer 206 to reduce the resistance of the side edge wire.

The first planarization layer 905 and the second planarization layer 906 terminate at the edge of the display region, are made of organic materials, are relatively thick, and may therefore form a stepped structure. In contrast, the first insulating layer 901, the second insulating layer 902, the third insulating layer 903, and the fourth insulating layer 904 are typically made of inorganic materials, are generally thin, therefore form directly a slope, and are coplanar with the surface of the first chamfer 11. Accordingly, for the non-display region, the filling layer 908, the light-shielding layer 23/90, the optical clear adhesive layer 70/90, and the surface film 60 are set on the steps. The filling layer 908 fills the stepped gap formed by the planarization layers.

It should be noted that FIG. 13 to FIG. 16 are merely schematic illustrations of the display panel structure, and the specific film layer design can be adjusted based on practical conditions.

Continuing to refer to FIG. 13, in one or more embodiments, the display functional layer 20 includes a pixel circuit layer 21 and light-emitting elements 22. The pixel circuit layer 21 includes at least one planarization layer (two planarization layers 905 and 906 are shown in FIG. 13 as an example, but this is not intended to limit the embodiments of the present disclosure). The display panel includes a display region AA and a non-display region NA. The planarization layers are located in the display region AA, with their edges located between the display region AA and the edge of the base substrate 10. The display panel further includes the filling layer 908 located in the non-display region NA and filling at least at the edges of the planarization layers.

In one or more embodiments, the display panel further includes a light-shielding layer 23/90 located on the side of the filling layer 908 facing away from the base substrate 10, and an optical clear adhesive layer 70/90 located on the side of the light-shielding layer 23/90 facing away from the base substrate 10.

The light-shielding layer 23/90 forms a black matrix for shielding the pixel circuits. The light-shielding layer 23/90 is provided with multiple holes, within which the light-emitting elements are disposed. The optical clear adhesive layer 70/90 is configured to attach the surface film 60 to the surface of the display panel.

In one or more embodiments, the filling layer 908, the light-shielding layer 23/90, and the optical clear adhesive layer 70/90 are all formed using an inkjet printing process.

The filling layer 908, the light-shielding layer 23/90, and the optical clear adhesive layer 70/90 can all be made of organic materials. The inkjet printing process achieves high precision and facilitates cost reduction.

Referring to FIG. 13, in one or more embodiments, the first edge has no side edge wires, and the end surface of the filling layer 908 facing away from the display region is flat. The end surface of the filling layer 908 is contiguous and coplanar with the surface of the first chamfer 11.

Referring to FIG. 16, in one or more embodiments, the first edge is further provided with an edge wire, and the end surface of at least one of the filling layer 908, the light-shielding layer 23/90, and the optical clear adhesive layer 70/90 facing away from the display region is curved. In one or more embodiments, the first filling adhesive 40 covers the edges of the filling layer 908, light-shielding layer 23/90, and optical clear adhesive layer 70/90 facing away from the display region.

The convex end surfaces of the filling layer 908, light-shielding layer 23/90, and optical clear adhesive layer 70/90 are shown for illustration purposes only. In other embodiments, their curved shapes can be configured based on practical requirements, such as in concave shapes or in a wave-like shape formed by the surfaces of the multiple film layers. This design can be tailored to practical conditions in specific implementations.

It is to be noted that in other embodiments, for example, for an edge with side edge wires, the end surfaces of the filling layer 908, light-shielding layer 23/90, and optical clear adhesive layer 70/90 may also be configured to be contiguous and coplanar with the surface of the first chamfer 11. For an edge without side edge wires, the end surfaces of the filling layer 908, light-shielding layer 23/90, and optical clear adhesive layer 70/90 may also be configured as curved surfaces.

A display device is further provided according to embodiments of the present disclosure, which includes any of the display panels provided in the above embodiments.

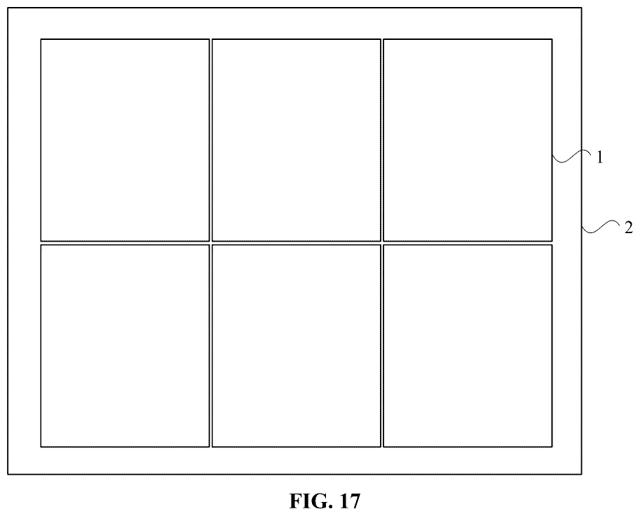

In one or more embodiments, the display device includes at least two spliced display panels, where the first edges of the display panels are splicing edges, and the splicing edge of one display panel is adjacent to the splicing edge of another display panel. For example, FIG. 17 is a schematic structural diagram of a display device according to an embodiment of the present disclosure. Referring to FIG. 17, the display device 2 includes multiple spliced display panels 1, with the splicing edge of each display panel 1 adjacent to a splicing edge of another display panel 1.

Note that the above are only preferred embodiments of the present disclosure and the technical principles used. The person skilled in the art will understand that the present disclosure is not limited to the specific embodiments described here, and that various obvious variations, readjustments, mutual combinations, and substitutions may be made for the person skilled in the art without departing from the scope of protection of the present disclosure. Therefore, although the present disclosure is described in more detail through the above embodiments, the present disclosure is not limited to the above embodiments, and may include other equivalent embodiments without departing from the concept of the present disclosure, and the scope of the present disclosure is determined by the scope of the attached claims.

What is claimed is:

1. A display panel, comprising
a base substrate; and
a display functional layer provided on one side of the base substrate,
wherein the display panel comprises at least one first edge, and at a first edge of the at least one first edge, the base substrate comprises a first chamfer located at a side surface of the base substrate facing the display functional layer and a second chamfer located at a side surface of the base substrate away from the display functional layer; and
wherein in a first direction, the first chamfer at least overlaps with a first filling adhesive, and a non-chamfered region or the second chamfer at least overlaps with a second filling adhesive, a viscosity of the second filling adhesive is greater than a viscosity of the first filling adhesive, and the first direction is parallel to a plane in which the base substrate is located and the first direction intersects the first edge.

2. The display panel according to claim 1, wherein the first chamfer is filled with the first filling adhesive, and the second chamfer is filled with the second filling adhesive.

3. The display panel according to claim 1, wherein the first edge is a splicing edge, and when the display panel is spliced with at least one other display panel, the splicing edge of the display panel is adjacent to a splicing edge of the at least one other display panel.

4. The display panel according to claim 1, further comprising a surface film located on a side of the display functional layer facing away from the base substrate, wherein at least part of an end surface of the second filling adhesive facing away from a display region is flush with an end surface of the surface film at the first edge.

5. The display panel according to claim 4, wherein in the first direction, the first chamfer overlaps with the second filling adhesive, and an end surface of the second filling adhesive facing away from the display region is flush with the end surface of the surface film at the first edge.

6. The display panel according to claim 1, further comprising a surface film located on a side of the display functional layer facing away from the base substrate, wherein
in a region where the first chamfer is located or in both a region where the first chamfer is located and the non-chamfered region, the second filling adhesive exposes an end surface of the first filling adhesive facing away from a display region, and the end surface of the first filling adhesive facing away from the display region, an end surface of the second filling adhesive facing away from the display region, and an end surface of the surface film at the first edge are flush with each other.

7. The display panel according to claim 4, further comprising at least one first functional layer located between the surface film and the base substrate, wherein an end surface of a first functional layer of the at least one first functional layer facing a side of the first edge is contiguous and coplanar with a surface of the first chamfer, or at least part of the first functional layer extends toward the surface film in an extension direction of the surface of the first chamfer.

8. The display panel according to claim 4, further comprising at least one first functional layer located between the surface film and the base substrate, wherein a first functional layer of the at least one first functional layer comprises a plurality of sub-layers stacked sequentially in a direction from the base substrate toward the display functional layer, wherein end surfaces of the plurality of sub-layers are sequentially tapered toward the display region in a direction from the first edge toward the display region, forming a profile of the first functional layer in a shape of step or slope.

9. The display panel according to claim 8, wherein the plurality of sub-layers comprise one or more of a plurality of insulating layers, a light-shielding layer, and an optical clear adhesive layer.

10. The display panel according to claim 1, wherein the first edge is further provided with a side edge encapsulation layer, and the side edge encapsulation layer covers a side edge of the display functional layer and a side edge of the base substrate that are located at the first edge in a direction perpendicular to the first edge and parallel to a plane in which the display panel is located.

11. The display panel according to claim 1, wherein the first edge is further provided with a side edge wire, a first end of the side edge wire is located within the display functional layer, and the side edge wire extends along an edge of the base substrate to a surface of the base substrate away from a side of the display functional layer.

12. The display panel according to claim 11, further comprising a side edge encapsulation layer, wherein the side edge encapsulation layer covers the side edge wire located at the edge of the base substrate and covers at least part of the side edge wire located at the surface of the base substrate away from the side of the display functional layer.

13. The display panel according to claim 1, further comprising a protective layer, wherein a projection of the protective layer on the first edge of the display panel covers the first chamfer, the second chamfer, and a non-chamfered region between the first chamfer and the second chamfer.

14. The display panel according to claim 13, wherein the protective layer comprises a first protective layer, and in a region where the first chamfer is located, the first protective layer is located on a side of the first filling adhesive facing the base substrate, and in the non-chamfered region, the first protective layer is located on the side of the first filling adhesive facing the base substrate or a side of the second filling adhesive facing the base substrate, and in a region where the second chamfer is located, the first protective layer is located on the side of the second filling adhesive facing the base substrate.

15. The display panel according to claim 14, further comprising at least one first functional layer located on a side of the base substrate facing the display functional layer and facing the first edge, wherein the first protective layer further covers an end surface of the at least one first functional layer on a side facing away from a display region, or one end of the first protective layer extends into the display functional layer.

16. The display panel according to claim 14, wherein a thickness of the first protective layer in the region where the first chamfer is located is greater than a thickness of the first protective layer in the non-chamfered region, and a thickness of the first protective layer in the region where the second chamfer is located is greater than the thickness of the first protective layer in the non-chamfered region.

17. The display panel according to claim 13, wherein the protective layer comprises a second protective layer; in a region where the first chamfer is located, the second protective layer is located on a side of the first filling adhesive facing away from the base substrate; in the non-chamfered region, the second protective layer is located on the side of the first filling adhesive or the second filling adhesive facing away from the base substrate; and in a region where the second chamfer is located where the second chamfer is located, the second protective layer is located on a side of the second filling adhesive facing away from the base substrate.

18. The display panel according to claim 17, wherein the second protective layer comprises a first region, a second region, and a third region connected in sequence; and
in a direction from the display functional layer toward the base substrate, the first region covers the first chamfer; in the first direction, the second region covers the first edge; and
in a direction from the base substrate toward the display functional layer, the third region covers the second chamfer.

19. The display panel according to claim 18, wherein the first filling adhesive is filled within a region enclosed by the first region, the second protective layer at a first part of the second region, and the first chamfer; the second filling adhesive is filled within a region enclosed by the third region, the second protective layer at a second part of the second region, and the second chamfer; and at least one of the first filling adhesive or the second filling adhesive is filled between the second protective layer at a third part of the second region and the non-chamfered region; and
the first part of the second region, the third part of the second region, and the second part of the second region are arranged sequentially in the direction from the display functional layer toward the base substrate.

20. The display panel according to claim 13, wherein the protective layer is a blackened layer.

21. The display panel according to claim 1, wherein the first filling adhesive and the second filling adhesive overlap in the first direction in the non-chamfered region between the first chamfer and the second chamfer; and
in a region of the overlapping, the first filling adhesive is located on a side of the second filling adhesive facing the base substrate.

22. The display panel according to claim 21, wherein the first filling adhesive extends to the second chamfer, and a surface of the first filling adhesive facing the second chamfer is contiguous and coplanar with a surface of the second chamfer.

23. The display panel according to claim 1, wherein the first filling adhesive covers a region where the first chamfer is located, and the second filling adhesive covers a region where the second chamfer is located; one or both of the first filling adhesive and the second filling adhesive cover the non-chamfered region; the first filling adhesive and the second filling adhesive are contiguous with each other, and edges of the first filling adhesive and the second filling adhesive facing toward an outer side of the base substrate are flush.

24. The display panel according to claim 1, wherein the display functional layer comprises a pixel circuit layer and a light-emitting element, and the pixel circuit layer comprises at least one planarization layer;
the display panel comprises a display region and a non-display region, the planarization layer is located in the display region, and an edge of the planarization layer is located between the display region and an edge of the base substrate; and
the display functional layer further comprises a filling layer, the filling layer is located in the non-display region, and the filling layer at least fills at the edge of the planarization layer.

25. The display panel according to claim 24, further comprising a light-shielding layer located on a side of the filling layer facing away from the base substrate, and an optical clear adhesive layer located on a side of the light-shielding layer facing away from the base substrate.

26. The display panel according to claim 25, wherein the filling layer, the light-shielding layer, and the optical clear adhesive layer are all formed using an inkjet printing process.

27. The display panel according to claim 24, wherein no edge wire is arranged at the first edge, an end surface of the filling layer away from the display region is flat, and the end surface of the filling layer is contiguous and coplanar with a surface of the first chamfer.

28. The display panel according to claim 25, wherein an edge wire is arranged at the first edge, and an end surface of at least one of the filling layer, the light-shielding layer, and the optical clear adhesive layer away from the display region is a curved surface.

29. The display panel according to claim 28, wherein the first filling adhesive covers the edges of the filling layer, the light-shielding layer, and the optical clear adhesive layer away from the display region.

30. A display device, comprising at least one display panel, wherein each of the at least one display panel comprises:
a base substrate; and
a display functional layer provided on one side of the base substrate,
wherein the display panel comprises at least one first edge, and at a first edge of the at least one first edge, the base substrate comprises a first chamfer located at a side surface of the base substrate facing the display functional layer and a second chamfer located at a side surface of the base substrate away from the display functional layer; and
wherein in a first direction, the first chamfer at least overlaps with a first filling adhesive, and a non-chamfered region or the second chamfer at least overlaps with a second filling adhesive, a viscosity of the second filling adhesive is greater than a viscosity of the first filling adhesive, and the first direction is parallel to a plane in which the base substrate is located and the first direction intersects the first edge.

31. The display device according to claim 30, comprising at least two display panels which are spliced to each other, wherein each of the at least one first edge is a splicing edge, and a splicing edge of a display panel of the at least two display panels is adjacent to a splicing edge of another display panel of the at least two display panels.
